(19) United States
(12) Patent Application Publication
(10) Pub. No.: US 2024/0297283 A1
(43) Pub. Date: Sep. 5, 2024

(54) LIGHT EMITTING DIODE CHIP, DISPLAY SUBSTRATE AND DISPLAY DEVICE

(71) Applicants: BOE MLED Technology Co., Ltd., Beijing (CN); BOE Technology Group Co., Ltd., Beijing (CN)

(72) Inventors: Yuanda Lu, Beijing (CN); Jiawei Zhao, Beijing (CN); Zhijun Xiong, Beijing (CN); Shanwei Yang, Beijing (CN); Xueqiao Li, Beijing (CN); Yuanhao Sun, Beijing (CN); Junjie Ma, Beijing (CN)

(73) Assignees: BOE MLED Technology Co., Ltd., Beijing (CN); BOE Technology Group Co., Ltd., Beijing (CN)

(21) Appl. No.: 18/027,553

(22) PCT Filed: Mar. 31, 2022
(86) PCT No.: PCT/CN2022/084334

§ 371 Date: Mar. 21, 2023

(51) Int. Cl. H01L 33/62; H01L 25/075

(52) U.S. Cl. CPC H01L 33/62; H01L 25/0753

(57) ABSTRACT

Provided is a light emitting diode chip, including: a base substrate; at least two light emitting units disposed on the base substrate, wherein the at least two light emitting units include adjacent first light emitting unit and second light emitting unit, and each of the first light emitting unit and the second light emitting unit includes: a first semiconductor layer disposed on the base substrate; a light emitting layer disposed on the first semiconductor layer away from the base substrate; and a second semiconductor layer disposed on the light emitting layer away from the base substrate, wherein the light emitting diode chip further includes a bridging part for conducting, and the bridging part is configured to electrically connect the second semiconductor layer of the first light emitting unit with the first semiconductor layer of the second light emitting unit.

### CROSS-REFERENCE TO RELATED APPLICATION

This application is a Section 371 National Stage Application of International Application No. PCT/CN2022/084334, filed on Mar. 31, 2022, entitled “DISPLAY SUBSTRATE, TILED DISPLAY PANEL AND DISPLAY DEVICE”, the content of which is hereby incorporated by reference in its entirety.

### TECHNICAL FIELD

The present disclosure relates to a field of display technology, and in particular, to a light emitting diode chip, a display substrate and a display device.

### BACKGROUND

Light Emitting Diode (abbreviated as LED) technology has developed for nearly 30 years, and its application scope has been continuously expanded. For example, it may be applied in a display field, as a backlight source for a display device or as an LED display screen. With a development of technology, Mini Light Emitting Diode (abbreviated as Mini LED) has gradually become a research hotspot in the field of display technology. For example, Mini LED, with its advantages of high brightness, high contrast, fast response and low power dissipation, has gradually become a key research direction in the next generation of display technology. As a light emitting element, an improvement of the performance of the Mini LED chip is very important.

The above information disclosed in this part is only used to understand the background of the invention concept of the present disclosure. Therefore, the above information may include information that does not constitute the existing technologies.

### SUMMARY

In order to solve at least one aspect of the above problems, the embodiment of the present disclosure provides a light emitting diode chip, including: a base substrate; at least two light emitting units disposed on the base substrate, wherein the at least two light emitting units include adjacent first light emitting unit and second light emitting unit, and each of the first light emitting unit and the second light emitting unit includes: a first semiconductor layer disposed on the base substrate: a light emitting layer disposed on the first semiconductor layer away from the base substrate; and a second semiconductor layer disposed on the light emitting layer away from the base substrate, wherein the light emitting diode chip further includes a bridging part for conducting, and the bridging part is configured to electrically connect the second semiconductor layer of the first light emitting unit with the first semiconductor layer of the second light emitting unit: wherein the first light emitting unit includes a first side wall close to the second light emitting unit, the bridging part includes an inclined connecting part disposed on the first side wall of the first light emitting unit, and the inclined connecting part is inclined with respect to a surface of the base substrate facing the at least two light emitting units; and wherein the light emitting diode chip further includes a first insulation layer, the first insulation layer includes an inclined part sandwiched between the first side wall of the first light emitting unit and the inclined connecting part, at least a part of the inclined part is inclined with respect to the surface of the base substrate facing the at least two light emitting units at an inclination θ, and the inclination θ≤60°.

According to some exemplary embodiments, the light emitting diode chip includes at least two bridging parts, each of the at least two bridging parts is configured to electrically connect the second semiconductor layer of the first light emitting unit with the first semiconductor layer of the second light emitting unit, and orthographic projections of the at least two bridging parts on the base substrate are spaced from each other.

According to some exemplary embodiments, the inclined part includes a first side surface close to the first light emitting unit, a part of the first side surface is in contact with the first semiconductor layer of the first light emitting unit, and the first side surface is inclined with respect to the surface of the base substrate facing the at least two light emitting units at the inclination θ.

According to some exemplary embodiments, the inclined part includes a first side surface close to the first light emitting unit, a part of the first side surface is in contact with the first semiconductor layer of the first light emitting unit, and includes a first sub-side surface and a second sub-side surface: the first sub-side surface is inclined with respect to the surface of the base substrate facing the at least two light emitting units at an inclination a, the second sub-side surface is inclined with respect to the surface of the base substrate facing the at least two light emitting units at the inclination θ, and the inclination a is not equal to the inclination θ.

According to some exemplary embodiments, the first sub-side surface is closer to the base substrate than the second sub-side surface; and/or, the inclination a is greater than the inclination θ.

According to some exemplary embodiments, the first side surface further includes a platform surface connecting the first sub-side surface and the second sub-side surface, and the platform surface is parallel to the surface of the base substrate facing the at least two light emitting units.

According to some exemplary embodiments, the first side surface further includes a third sub-side surface in contact with the light emitting layer of the first light emitting unit and a fourth sub-side surface in contact with the second semiconductor layer of the first light emitting unit: each of the third sub-side surface and the fourth sub-side surface is inclined with respect to the surface of the base substrate facing the at least two light emitting units at the inclination θ.

According to some exemplary embodiments, the first insulation layer further includes a first plane part, the first plane part is parallel to the surface of the base substrate facing the at least two light emitting units, the first plane part is located in an interval between the first light emitting unit and the second light emitting unit, and a width of the first plane part is less than or equal to a width of the interval.

According to some exemplary embodiments, the first plane part includes a first sub-plane part and a second sub-plane part, the first sub-plane part is closer to the first light emitting unit than the second sub-plane part, and a height of the first sub-plane part is greater than a height of the second sub-plane part.

According to some exemplary embodiments, the light emitting diode chip further includes an avoidance structure: the avoidance structure includes a first avoidance concave part located on at least a part of the first side wall, the first avoidance concave part causes at least a part of the first side wall to be concaved towards a first direction, and the first direction is a direction directing from the second light emitting unit to the first light emitting unit; and/or, the second light emitting unit includes a second side wall close to the first light emitting unit, the avoidance structure includes a second avoidance concave part located on at least a part of the second side wall, the second avoidance concave part causes at least a part of the second side wall to be concaved towards a second direction, and the second direction is a direction directing from the first light emitting unit to the second light emitting unit.

According to some exemplary embodiments, the bridging part includes a third side wall facing an interval between the first light emitting unit and the second light emitting unit, the avoidance structure includes a third avoidance concave part located on at least a part of the third side wall, the third avoidance concave part causes at least a part of the third side wall to be concaved towards a third direction, and the third direction is a direction directing from the interval to a body of the bridging part.

According to some exemplary embodiments, a contour of an orthographic projection of the light emitting diode chip on the base substrate has a shape of square.

According to some exemplary embodiments, orthographic projections of the at least two light emitting units on the base substrate are arranged +symmetrically with respect to a geometric center of the square.

In another aspect, there is provided a display substrate including a light emitting diode chip as described above.

In yet another aspect, there is provided a display device including a light emitting diode chip as described above.

### BRIEF DESCRIPTION OF DRAWINGS

Other purposes and advantages of the present disclosure will be apparent from the following description of the present disclosure with reference to the accompanying drawings, and may help to have a comprehensive understanding of the present disclosure.

FIG. 1 is a schematic plan view of a light emitting diode chip according to some exemplary embodiments of the present disclosure.

FIG. 2 is a cross-sectional view of the light emitting diode chip according to some exemplary embodiments of the present disclosure in FIG. 1 along line AA′.

FIG. 3 is an equivalent circuit diagram of a light emitting diode chip according to some exemplary embodiments of the present disclosure.

FIG. 4 is a cross-sectional view of the light emitting diode chip according to some other exemplary embodiments of the present disclosure in FIG. 1 along line AA.

FIG. 5 is a cross-sectional view of the light emitting diode chip according to some yet other exemplary embodiments of the present disclosure in FIG. 1 along line AA′.

FIG. 6 is a schematic plan view of a light emitting diode chip according to some exemplary embodiments of the present disclosure, in which a plurality of bridging parts are schematically shown.

FIG. 7A is a schematic plan view of a light emitting diode chip according to some exemplary embodiments of the present disclosure, in which a light emitting region with reduced area is schematically shown.

FIG. 7B is a cross-sectional view of the light emitting diode chip according to some exemplary embodiments of the present disclosure in FIG. 7A along line BB′.

FIG. 7C is a partial enlarged view of part I in FIG. 7B.

FIG. 8 is a schematic diagram of a current-efficiency curve of a light emitting diode chip according to some exemplary embodiments of the present disclosure.

FIG. 9A is a schematic plan view of a light emitting diode chip according to some exemplary embodiments of the present disclosure, in which an avoidance structure is schematically shown.

FIG. 9B is a schematic plan view of a light emitting diode chip according to some exemplary embodiments of the present disclosure, in which a plurality of bridging parts and a plurality of avoidance structures are schematically shown.

FIG. 10 schematically shows a process of transferring a light emitting diode chip to the base substrate according to some exemplary embodiments of the present disclosure.

FIG. 11 is a plan schematic view of a light emitting diode chip according to some exemplary embodiments of the present disclosure, in which a contour shape of the light emitting diode chip is schematically shown.

It should be noted that, for the sake of clarity, in the drawings used to describe the embodiments of the present disclosure, the sizes of layers, structures or regions may be enlarged or reduced, that is, these drawings are not drawn according to the actual scale.

### DETAILED DESCRIPTION

In the following description, for the purpose of explanation, many specific details are set forth to provide a comprehensive understanding of various exemplary embodiments. However, it is obvious that various exemplary embodiments may be implemented without these specific details or with one or more equivalent arrangements. In other cases, well-known structures and devices are shown in block diagram form to avoid unnecessary ambiguity of various exemplary embodiments. In addition, various exemplary embodiments may be different, but need not be exclusive. For example, without departing from the inventive concept, the specific shapes, configurations and characteristics of the exemplary embodiment may be used or implemented in another exemplary embodiment.

In the drawings, for the purpose of clarity and/or description, the size and relative size of the elements may be enlarged. In this way, the size and relative size of each element need not be limited to the size and relative size shown in the drawings. When the exemplary embodiments may be implemented differently, the specific process sequence may be executed differently from the described sequence. For example, two continuously described processes may be substantially performed simultaneously or in a reverse order of the described sequence. In addition, the same reference numerals represent the same elements.

When an element is described as being “on”, “connected to”, or “coupled to” another element, the element may be directly on, directly connected to, or directly coupled to the other element, or intermediate elements may be existed. However, when an element is described as being “directly on”, “directly connected to”, or “directly coupled to” another element, there is no intermediate element existed. Other terms and/or expressions used to describe a relationship between elements should be interpreted in a similar fashion, e.g., “between” versus “directly between”, “adjacent” versus “directly adjacent”, or “on” versus “directly on” etc. . . . Furthermore, the term “connected” may refer to a physical connection, an electrical connection, a communication connection, and/or a fluid connection. In addition, an X axis, a Y axis and a Z axis are not limited to a three axes of a rectangular coordinate system, and may be interpreted in a broader sense. For example, the X, Y, and Z axes may be perpendicular to each other, or may represent different directions that are not perpendicular to each other. For a purpose of the present disclosure, “at least one of X, Y, and Z” and “at least one of the selected groups consisted of X, Y, and Z” may be interpreted as X only, Y only, Z only, or such as any combination of two or more of X, Y and Z in XYZ, XYY, YZ and ZZ. As used herein, the term “and/or” includes any and all combinations of one or more of the associated listed items.

It should be understood that, although the terms first, second, etc. may be used herein to describe various elements, these elements should not be limited by these terms. These terms are only used to distinguish one component from another. For example, without departing from the scope of the example embodiment, a first element may be referred as a second element. Similarly, the second element may be referred as the first element.

In the present disclosure, an inorganic light emitting diode refers to a light emitting element made of inorganic material, wherein LED refers to an inorganic light emitting element different from OLED. Specifically, the inorganic light emitting element may include a Mini Light Emitting Diode (abbreviated as Mini LED) and a Micro Light Emitting Diode (abbreviated as Micro LED). Among them, the Mini Light Emitting Diode (i.e. Mini LED) refers to a small light emitting diode of which a grain size is in a range of a grain size of Micro LED to a grain size of traditional LED. Generally, the grain size of Mini LED may be in a range of 100 μm to 300 μm.

Some exemplary embodiments of the present disclosure provide a light emitting diode chip, including: a base substrate: at least two light emitting units disposed on the base substrate, wherein the at least two light emitting units include adjacent first light emitting unit and second light emitting unit, and each of the first light emitting unit and the second light emitting unit includes: a first semiconductor layer disposed on the base substrate: a light emitting layer disposed on the first semiconductor layer away from the base substrate; and a second semiconductor layer disposed on the light emitting layer away from the base substrate, wherein the light emitting diode chip further includes a bridging part for conducting, and the bridging part is used to electrically connect the second semiconductor layer of the first light emitting unit with the first semiconductor layer of the second light emitting unit: wherein the first light emitting unit includes a first side wall close to the second light emitting unit, the bridging part includes an inclined connecting part disposed on the first side wall of the first light emitting unit, and the inclined connecting part is inclined with respect to a surface of the base substrate facing the at least two light emitting units; and wherein the light emitting diode chip further includes a first insulation layer, the first insulation layer includes an inclined part sandwiched between the first side wall of the first light emitting unit and the inclined connecting part, at least a part of the inclined part is inclined with respect to the surface of the base substrate facing the at least two light emitting units at an inclination θ, and the inclination θ≤60°. In the embodiment of the present disclosure, the inclination 0 (also referred as a slope angle) of the inclined part with respect to an upper surface of the base substrate is controlled within 60°, so as to ensure an integrity of a subsequent bridging film layer, thereby avoiding a crack of the film layer of the bridging part.

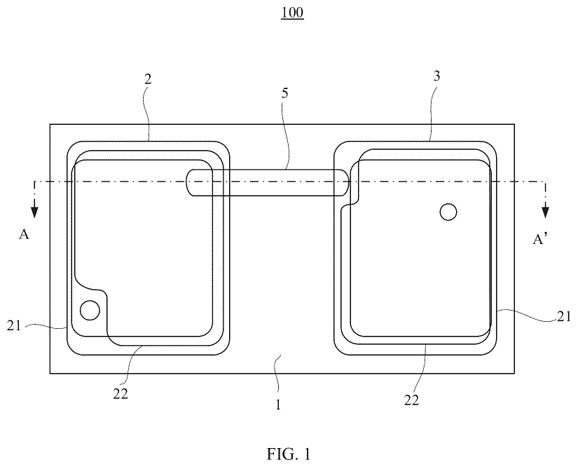

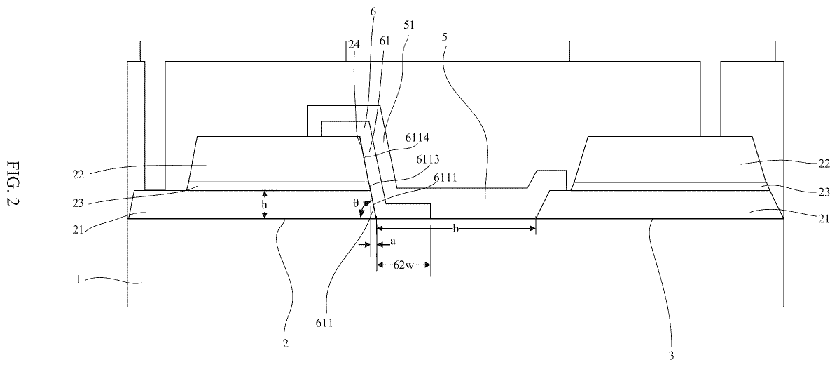

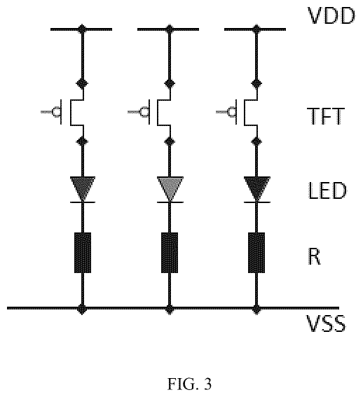

FIG. 1 is a schematic plan view of a light emitting diode chip according to some exemplary embodiments of the present disclosure. FIG. 2 is a cross-sectional view of the light emitting diode chip according to some exemplary embodiments of the present disclosure in FIG. 1 along line AA′. FIG. 3 is an equivalent circuit diagram of a light emitting diode chip according to some exemplary embodiments of the present disclosure.

In the embodiment of the present disclosure, there is provided a light emitting diode chip. For example, the light emitting diode chip may be a Mini LED high voltage chip. Specifically, it may include a chip included at least two diodes in series, with high voltage threshold and low working current. Mini LED high voltage chip may effectively improve a light emitting brightness when applied in a backlight module and may effectively reduce a driving current when applied in a display panel, thereby saving power dissipation.

With reference to FIG. 3, in an equivalent circuit, a voltage difference between both ends of a line is VDD-VSS, wherein VDD represents a first voltage and VSS represents a second voltage. The current on the line is determined by brightness required by the LED. In particular, due to different lighting voltages of LEDs of red pixel, green pixel and blue pixel (e.g., red: ˜ 1.3V, green: ˜ 1.7V, blue: ˜ 2.0V(@luA), a pixel circuit may be divided into three channels for control. By taking an equivalent circuit of blue pixel as an example, an overall power dissipation on a line is P=(VDD-VSS) * I=(VTFT+VLED+VR) * I, wherein I is a current flowing through the LED, VTFT is a voltage difference (>2.8V) of a transistor TFT switch, VLED is a voltage value (˜3V) when the LED is being used, and VR is a voltage difference required for a line resistance value. From a calculation formula of power dissipation P, it may be seen that the voltage value of TFT is close to the voltage value when the LED is being used, and a power dissipation ratio of TFT is relatively high. In the embodiment of the present disclosure, a high voltage LED may be used to replace a normal voltage LED. In a case of constant brightness, a line current value (i.e. I is reduced) may be reduced, a ratio of VLED may be increased, thereby reducing the overall power dissipation.

With reference to FIGS. 1 and 2, according to some exemplary embodiments of the present disclosure, the light emitting diode chip 100 may include: a base substrate 1: at least two light emitting units disposed on the base substrate 1, wherein the at least two light emitting units include adjacent first light emitting unit 2 and second light emitting unit 3, and each of the first light emitting unit 2 and the second light emitting unit 3 includes: a first semiconductor layer 21 disposed on the base substrate: a light emitting layer 23 disposed on the first semiconductor layer away from the base substrate; and a second semiconductor layer 22 disposed on the light emitting layer away from the base substrate.

For example, there are various types of base substrate 1, which may be disposed as desired in practice. For example, the base substrate 1 may be a gallium phosphide (GaP) base substrate, a gallium arsenide (GaAs) base substrate, a silicon base substrate, a silicon carbide base substrate or a sapphire base substrate, etc. . . .

The first semiconductor layer 21 may be one of an N-type semiconductor layer and a P-type semiconductor layer, and the second semiconductor layer 22 may be the other one of the N-type semiconductor layer and the P-type semiconductor layer. Specifically, for example, for blue or green LED chips, the first semiconductor layer 21 may be an N-type semiconductor layer, and the second semiconductor layer 22 may be a P-type semiconductor layer. For example, for red LED chip, the first semiconductor layer 21 may be a P-type semiconductor layer, and the second semiconductor layer 22 may be an N-type semiconductor layer.

For example, an area of an orthographic projection of the second semiconductor layer 22 on the base substrate 1 is smaller than an area of an orthographic projection of the light emitting layer 23 on the base substrate 1, and the orthographic projection of the second semiconductor layer 22 on the base substrate 1 is located in the orthographic projection of the light emitting layer 23 on the base substrate 1. The area of the orthographic projection of the light emitting layer 23 on the base substrate 1 is smaller than the area of the orthographic projection of the first semiconductor layer 21 on the base substrate 1, and the orthographic projection of the light emitting layer 23 on the base substrate 1 is located in the orthographic projection of the first semiconductor layer 21 on the base substrate 1.

In the embodiment of the present disclosure, the light emitting diode chip 100 further includes a bridging part 5 for conducting, which is used to electrically connect the second semiconductor layer 22 of the first light emitting unit 2 with the first semiconductor layer 21 of the second light emitting unit 3.

The first light emitting unit 2 includes a first side wall 24 close to the second light emitting unit 3, the bridging part 5 includes an inclined connecting part 51 disposed on the first side wall 24 of the first light emitting unit, and the inclined connecting part 51 is inclined with respect to a surface of the base substrate facing the at least two light emitting units (i.e., an upper surface in FIG. 2).

The light emitting diode chip 100 further includes a first insulation layer 6, the first insulation layer 6 includes an inclined part 61 sandwiched between the first side wall 24 of the first light emitting unit and the inclined connecting part 51, at least a part of the inclined part 61 is inclined with respect to the surface of the base substrate facing the at least two light emitting units at an inclination θ, and the inclination θ≤60°.

According to a research of the inventors of the present disclosure, in a manufacturing process of the LED chip provided by the embodiment of the present disclosure, a slope angle θ of a bridging position is a key parameter in a process of manufacturing high-voltage chips in a process of etching into two light emitting units, that is, the inclination 0 (also referred as the slope angle) of the inclined part 61 with respect to the upper surface of the base substrate is the key parameter in the process of manufacturing high-voltage chips. When the inclination 0 (also referred as the slope angle) of the inclined part 61 with respect to the upper surface of the base substrate is controlled within 60° (i.e., controlling the inclination 0≤60°), it is possible to ensure the integrity of the subsequent bridging film layer (i.e., the bridging part 5), thereby avoiding the crack of the film layer of the bridging part 5.

With reference to FIG. 2, a is a distance between the top and bottom edges of the first semiconductor layer 21 (e.g. N-type layer), h is a thickness of the first semiconductor layer 21, and b is a minimum distance between the first semiconductor layers 21 of the two light emitting units 2 and 3. In order to ensure that a vertical distance of the bridging part 5 is as thick as possible, a smaller inclination 0 is better. The inclination 0 is determined by a and h. In order to maximize an area of the light emitting layer 23 and reduce an edge effect, a larger a is better. In this case, the inclination 0 is directly determined by the thickness h. If h is smaller, it is more beneficial for a bridging of the bridging part 5.

With continued reference to FIG. 2, the inclined part 61 includes a first side surface 611 close to the first light emitting unit 2, wherein a part of the first side surface 611 is in contact with the first semiconductor layer 21 of the first light emitting unit 2, and the first side surface 611 is inclined with respect to the surface of the base substrate facing the at least two light emitting units at the inclination θ. For example, the first side surface 611 includes a first sub-side surface 6111 in contact with the first semiconductor layer 21 of the first light emitting unit 2, a third sub-side surface 6113 in contact with the light emitting layer 23 of the first light emitting unit 2, and a fourth sub-side surface 6114 in contact with the second semiconductor layer 22 of the first light emitting unit 2. Each of the first sub-side surface 6111, the third sub-side surface 6113 and the fourth sub-side surface 6114 is inclined with respect to the surface of the base substrate facing the at least two light emitting units at the inclination θ.

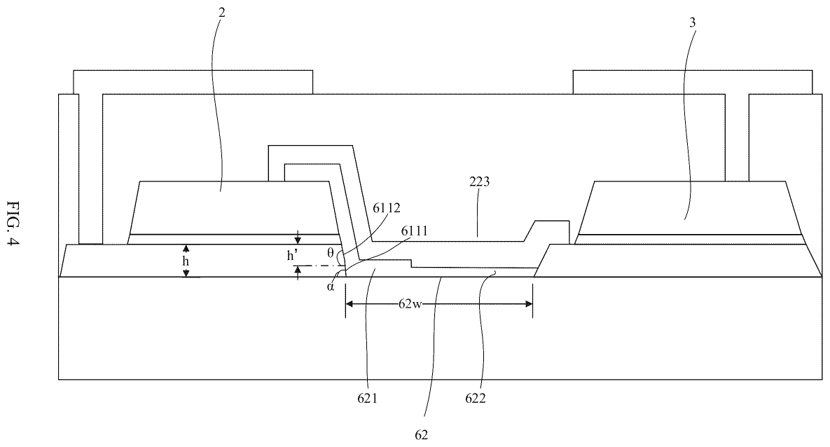

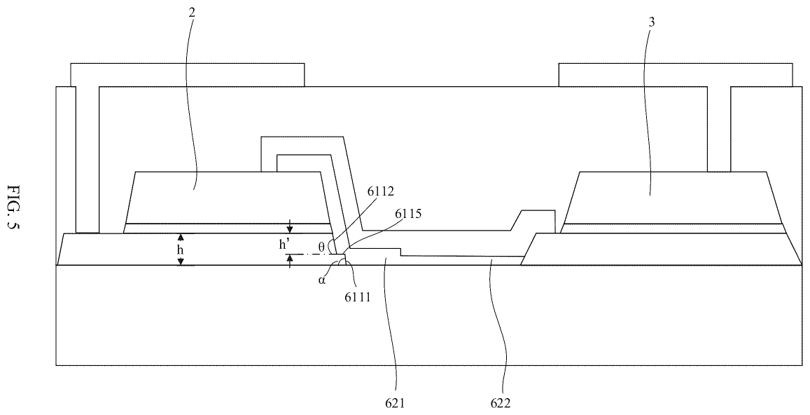

FIG. 4 is a cross-sectional view of the light emitting diode chip according to some other exemplary embodiments of the present disclosure in FIG. 1 along line AA′. FIG. 5 is a cross-sectional view of the light emitting diode chip according to some yet other exemplary embodiments of the present disclosure in FIG. 1 along line AA′.

With reference to FIG. 4 and FIG. 5, the first sub-side surface 6111 is inclined with respect to the surface of the base substrate facing the at least two light emitting units at an inclination a. The second sub-side surface 6112 is inclined with respect to the surface of the base substrate facing the at least two light emitting units at the inclination θ. The inclination a is not equal to the inclination θ. For example, the first sub-side surface 6111 is closer to the base substrate 1 than the second sub-side surface 6112. In some examples, the inclination a is greater than the inclination θ.

In the above embodiment, an effective thickness of the first semiconductor layer 21 is reduced from h to h′, causing the inclination 0 to be less than the inclination a. In this way, in a case that an area of the light emitting layer is not reduced, the inclination may be ensured. Therefore, the influence of the reduction of the area of the light emitting layer may be reduced, and the integrity of the subsequent bridging film layer (i.e., the bridging part 5) may be ensured at the same time, thereby avoiding the crack of the film layer of the bridging part 5.

With reference to FIG. 5, the first side surface 611 may further include a platform surface 6115 connecting the first sub-side surface 6111 and the second sub-side surface 6112, and the platform surface 6115 is parallel to the surface of the base substrate facing the at least two light emitting units. That is, the first insulation layer 6 may have a double-step structure, which is conducive to controlling the inclination θ≤60°.

In the embodiments shown in FIGS. 4 and 5, the first side surface 611 includes a third sub-side surface 6113 in contact with the light emitting layer 23 of the first light emitting unit 2 and a fourth sub-side surface 6114 in contact with the second semiconducting layer 22 of the first light emitting unit 2. Each of the third sub-side surface 6113 and the fourth sub-side surface 6114 is inclined with respect to the surface of the base substrate facing the at least two light emitting units at the inclination θ.

With reference to FIG. 2, FIG. 4 and FIG. 5, the first insulation layer 6 further includes a first plane part 62, which is parallel to the surface of the base substrate facing the at least two light emitting units. The first plane part 62 is located in an interval 223 between the first light emitting unit 2 and the second light emitting unit 3, and a width 62 of the first plane part 62 is less than or equal to a width of the interval. For example, the width of the interval may be expressed by a minimum interval b between the first semiconductor layers 21 of the two light emitting units 2 and 3.

With reference to FIG. 4 and FIG. 5, the first plane part 62 includes a first sub-plane part 621 and a second sub-plane part 622. The first sub-plane part 621 is closer to the first light emitting unit 2 than the second sub-plane part 622, and a height of the first sub-plane part 621 is greater than a height of the second sub-plane part 622. In this way, it is beneficial to reduce the effective thickness of the first semiconductor layer 21 from h to h′.

In the present disclosure, the expression “height” may refer to a dimension along an upper surface perpendicular to the base substrate 1.

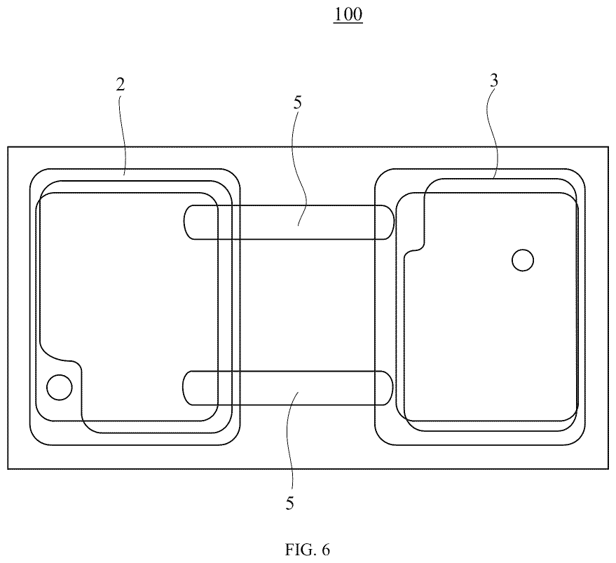

FIG. 6 is a schematic plan view of a light emitting diode chip according to some exemplary embodiments of the present disclosure, in which a plurality of bridging parts are schematically shown. With reference to FIG. 6, the light emitting diode chip 100 includes at least two bridging parts 5, each of which is used to electrically connect the second semiconductor layer 22 of the first light emitting unit 2 with the first semiconductor layer 21 of the second light emitting unit 3, and orthogonal projections of the at least two bridging parts 5 on the base substrate 1 are spaced from each other. In the embodiment of the present disclosure, since each light emitting unit is connected in series through the bridging part 5, the number of bridging units 5 disposed between two adjacent light emitting units may be increased to avoid the LED light off when a problem occurs in one bridging part (e.g., the crack of the film layer). That is, by disposing the plurality of bridging parts 5, a probability of dead light may be reduced.

In some exemplary embodiments of the present disclosure, the area of the orthographic projection of the second semiconductor layer 22 on the base substrate 1 is smaller than the area of the orthographic projection of the light emitting layer 23 on the base substrate 1, and the orthographic projection of the second semiconductor layer 22 on the base substrate 1 is located in the orthographic projection of the light emitting layer 23 on the base substrate 1. In a case of remaining the area of the light emitting layer 23 unchanged, an effective light emitting area of the light emitting diode chip may be reduced by reducing the area of the second semiconductor layer 22. Furthermore, in a case that the influence of the edge effect is not large and the voltage provided is the same, the light emitting diode chip may have a higher current density, and the effect of brightness uniformity of the plurality of light emitting diode chips in low gray scale may be achieved.

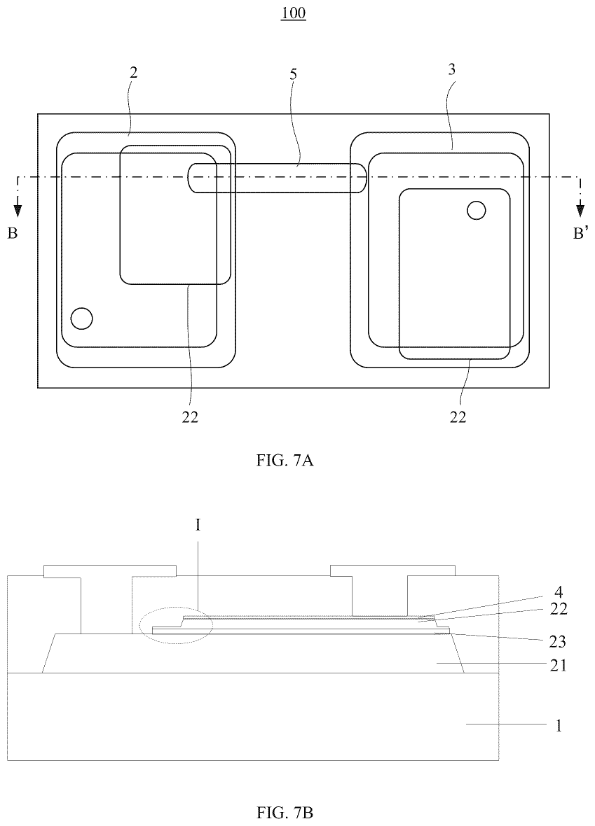

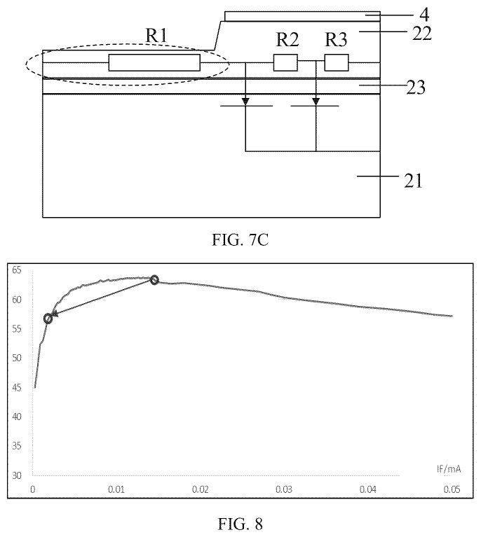

FIG. 7A is a schematic plan view of a light emitting diode chip according to some exemplary embodiments of the present disclosure, in which a light emitting region with reduced area is schematically shown. FIG. 7B is a cross-sectional view of the light emitting diode chip according to some exemplary embodiments of the present disclosure in FIG. 7A along line BB′. FIG. 7C is a partial enlarged view of part I in FIG. 7B. FIG. 8 is a schematic diagram of a current-efficiency curve of a light emitting diode chip according to some exemplary embodiments of the present disclosure. In FIG. 8, an abscissa is a current flowing through the LED and an ordinate is a light emitting efficiency of the LED.

With reference to FIG. 7A, FIG. 7B and FIG. 8, the light emitting diode chip further includes a conductor layer 4 located on a side of the second semiconductor layer 22 away from the light emitting layer 23, and a resistance of the conductor layer 4 is smaller than a resistance of the second semiconductor layer 22. An area of an orthographic projection of the conductor layer 4 on the base substrate 1 is substantially the same as an area of the orthographic projection of the second semiconductor layer 22 on the base substrate 1, and the orthographic projection of the conductor layer 4 on the base substrate 1 substantially overlaps with the orthographic projection of the second semiconductor layer 22 on the base substrate 1. Specifically, the conductor layer 4 may be a transparent electrode layer. For example, a material of the conductor layer 4 may include: indium tin oxide, indium zinc oxide or zinc oxide doped with aluminum. Specifically, the area of the orthographic projection of the conductor layer 4 on the base substrate 1 is substantially the same as the area of the orthographic projection of the second semiconductor layer 22 on the base substrate 1. It may be understood that a ratio of the difference between the two to any one of the two is less than 10%, and the orthographic projection of the conductor layer 4 on the base substrate 1 substantially overlaps with the orthographic projection of the second semiconductor layer 22 on the base substrate 1. It may be understood that a coincidence degree of the two may be in a range of 80% to 100%. In the embodiment of the present disclosure, the second semiconductor layer 22 (especially when the second semiconductor layer 22 is a P-type semiconductor layer) has a large lateral square resistance (104˜105 Ω/□). The conductor layer 4 is disposed, and the conductor layer 4 (e.g., indium tin oxide, square resistance is about 12 Ω/□) is taken as an expansion layer for expanding current, so as to cause more positive charges to have channels to lead to the light emitting layer 23, thereby emitting light with the negative charges of the first semiconductor layer 21 (N-type semiconductor layer) and improve the light emitting efficiency.

For example, by taking a light emitting diode chip being blue or green light emitting diode chip as an example, and the second semiconductor layer 22 being a P-type semiconductor layer as an example, due to the P-type semiconductor layer having a large lateral resistance, it is desired to use the conductor layer 4 as the expansion layer for expanding current, causing as many positive charges as possible to have channels to lead to a quantum trap layer, so that it is possible to emit light with the negative charges injected into the N-type layer. However, after an area of the P-type semiconductor layer is reduced, due to the upper layer has no conductive layer 4 and the thickness is reduced (a thinning region is shown by a dotted line coil in FIG. 7C), the lateral resistance of the remaining P-type semiconductor layer after being etched is far greater than that of the other non-etched parts, so as to reduce the actual light emitting area and achieve high current density at low current. Moreover, the remaining semiconductors in the thinning region may provide an effective protection for the light emitting layer 23. The actual effect may be seen in the equivalent circuit in FIG. 7C. The value of R1 is determined by the lateral resistance of the P-type semiconductor layer, and the values of R2 and R3 are determined by the lateral resistance of the conductor layer 4. R1 is far greater than R2 and R3. The current mainly flows from a region with the expansion layer (the conductor layer 4), thereby effectively reducing the light emitting area. A red light emitting diode chip is similar to a blue or green light emitting diode chip, but the lateral resistance of the N-type semiconductor layer in the red light emitting diode chip is small (e.g., the resistance of the N-type semiconductor material GaP is about 100 Ω/□). It is not desired to dispose the expansion layer, the actual reduction of the area of the N-type semiconductor layer may also improve the brightness uniformity of different light emitting diode chips in low gray scale.

In the above embodiment, by reducing the effective light emitting area of the light emitting diode chip, in a case that the influence of the edge effect is not large and the voltage provided is the same, the light emitting diode chip may have a higher current density and the effect of brightness uniformity of the plurality of light emitting diode chips in low gray scale may be achieved.

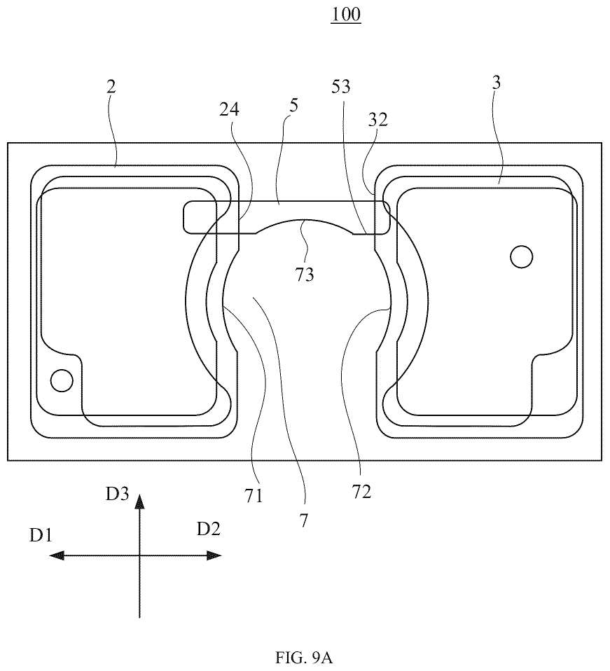

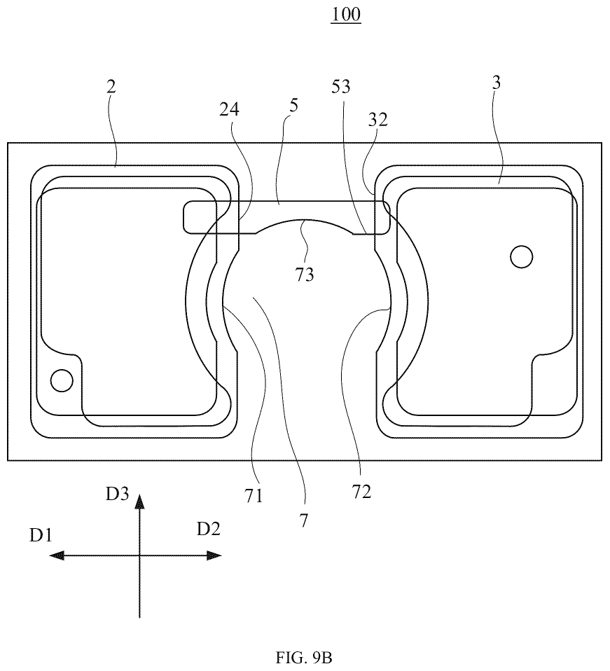

FIG. 9A is a schematic plan view of a light emitting diode chip according to some exemplary embodiments of the present disclosure, in which an avoidance structure is schematically shown. FIG. 9B is a schematic plan view of a light emitting diode chip according to some exemplary embodiments of the present disclosure, in which a plurality of bridging parts and a plurality of avoidance structures are schematically shown. FIG. 10 schematically shows a process of transferring a light emitting diode chip to the base substrate according to some exemplary embodiments of the present disclosure.

With reference to FIG. 9A, FIG. 9B and FIG. 10, in the manufacturing process of the Mini LED, the Mini LED module is made in a thimble manner. The thimble is in contact with an electrode surface of the LED (e.g., directly in contact with a film position made by the LED). In order to avoid a damage of LED caused by a thimble crystal fixation method, an avoidance structure may be made at the film position corresponding to the thimble, as shown in FIG. 9A and FIG. 9B.

In the embodiment of the present disclosure, the light emitting diode chip 100 may further include an avoidance structure 7. Specifically, the avoidance structure 7 includes a first avoidance concave part 71 located on at least a part of the first side wall 24, the first avoidance concave part 71 causes at least a part of the first side wall 24 to be concaved towards a first direction D1, and the first direction D1 is a direction directing from the second light emitting unit 3 to the first light emitting unit 2. The second light emitting unit 3 includes a second side wall 32 close to the first light emitting unit, the avoidance structure 7 includes a second avoidance concave part 72 located on at least a part of the second side wall 32, the second avoidance concave part 72 causes at least a part of the second side wall 32 to be concaved towards a second direction D2, and the second direction D2 is a direction directing from the first light emitting unit 2 to the second light emitting unit 3.

For example, a contour of the first avoidance concave part 71 and the second avoidance concave part 72 may be a part of a circle or ellipse, or may be a part of other types of arc curves. It should be noted that the embodiment of the present disclosure does not limit a contour shape of the first avoidance concave part 71 and the second avoidance concave part 72 too much, as long as it matches a shape of an outer contour of the thimble.

With reference to FIG. 9A, the bridging part 5 includes a third side wall 53 facing an interval between the first light emitting unit and the second light emitting unit, the avoidance structure 7 includes a third avoidance concave part 73 located on at least a part of the third side wall 53, the third avoidance concave part 73 causes at least a part of the third side wall 53 to be concaved towards a third direction D3, and the third direction D3 is a direction directing from the interval to a body of the bridging part.

With reference to FIG. 9B, in a case of disposing the plurality (e.g., two) of bridging parts 5, the avoidance structure 7 includes a third avoidance concave part 73 and a fourth avoidance concave part 74, both of which located on at least a part of the third side wall 53 of the two bridging parts 5, and both the third avoidance concave part 73 and the fourth avoidance concave 74 cause at least a part of the third side wall 53 to be concaved towards a third direction D3. The third direction D3 is a direction directing from the interval to a body of the bridging part.

In the above embodiments, by disposing the avoidance structure, the film layer may actively avoid a position for the thimble, so as to improve a yield of a thimble process.

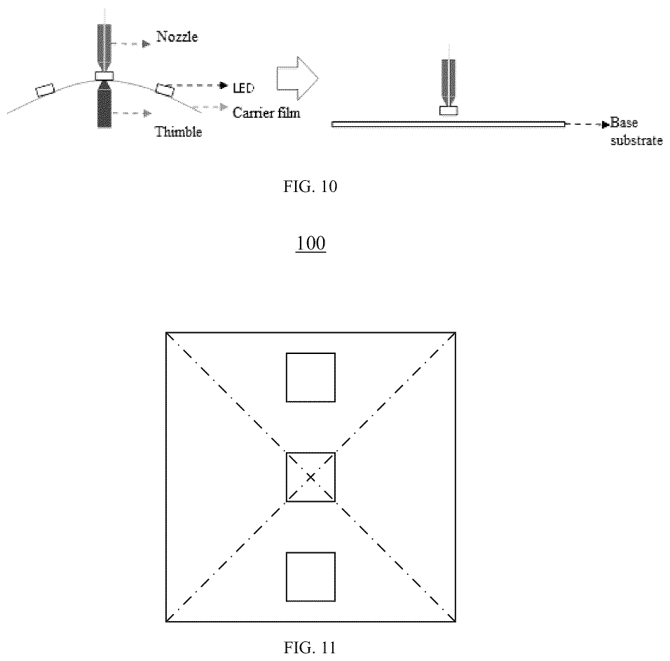

FIG. 11 is a plan schematic view of a light emitting diode chip according to some exemplary embodiments of the present disclosure, in which a contour shape of the light emitting diode chip is schematically shown. With reference to FIG. 11, in the embodiment of the present disclosure, a contour of an orthographic projection of the light emitting diode chip 100 on the base substrate 1 has a shape of square. Orthographic projections of the at least two light emitting units on the base substrate are arranged symmetrically with respect to a geometric center of the square. It should be noted that the geometric center herein refers to an intersection point of diagonals of a plan image. In this way, light shapes emitted by the light emitting diode chip may be more symmetrical, which is conducive to the optical design of the subsequent modules.

The embodiment of the present disclosure also provides a display substrate. For example, the display substrate may include a base substrate and a plurality of light emitting diode chips disposed on the base substrate. The light emitting diode chip may be the light emitting diode chip provided by any of the above embodiments.

For example, the base substrate may be a glass substrate. Optionally, the embodiments of the present disclosure are not limited to this. The base substrate may include, but not limited to, a printed circuit board (i.e., PCB), a flexible circuit board (i.e., FPC), etc. For example, the base substrate may include a glass substrate. The glass substrate may also be provided with a polyimide (PI) layer, or the glass substrate may also be connected with FPC and/or PCB.

Some exemplary embodiments of the present disclosure also provide a display device. The display device includes a light emitting diode chip provided by any of the above embodiments. The display device may be any product or component with display function. For example, the display device may be a smart phone, a portable phone, a navigation device, a television (TV), a car audio body, a laptop computer, a tablet computer, a portable multimedia player (PMP), a personal digital assistant (PDA), and so on.

It should be understood that the display substrate and the display device according to some exemplary embodiments of the present disclosure have all the characteristics and advantages of the light emitting diode chip described above, and these characteristics and advantages may be referred to the description of the light emitting diode chip above, and will not be repeated here.

As used herein, the terms “basically”, “about”, “substantially” and other similar terms are used as approximate terms rather than as terms of degree, and they are intended to explain the inherent deviation of measured or calculated values that will be recognized by those skilled in the art. Taking into account factors such as process fluctuations, measurement problems and errors related to the measurement of a specific amount (i.e., the limitations of the measurement system), the “about” or “substantially” used herein includes the stated value, and indicates that the specific value determined by those skilled in the art is within an acceptable deviation range. For example, “about” may be expressed within one or more standard deviations, or within +10% or +5% of the stated value.

Although some embodiments of the general inventive concept according to the present disclosure have been illustrated and explained, those skilled in the art will understand that these embodiments may be changed without departing from the principles and spirit of the general inventive concept of the present disclosure. The scope of the present disclosure is limited by the claims and their equivalents.

1. A light emitting diode chip, comprising:
a base substrate;
at least two light emitting units disposed on the base substrate, wherein the at least two light emitting units comprise adjacent first light emitting unit and second light emitting unit, and each of the first light emitting unit and the second light emitting unit comprises:
a first semiconductor layer disposed on the base substrate;
a light emitting layer disposed on the first semiconductor layer away from the base substrate; and
a second semiconductor layer disposed on the light emitting layer away from the base substrate,
wherein the light emitting diode chip further comprises a bridging part for conducting, and the bridging part is configured to electrically connect the second semiconductor layer of the first light emitting unit with the first semiconductor layer of the second light emitting unit;
wherein the first light emitting unit comprises a first side wall close to the second light emitting unit, the bridging part comprises an inclined connecting part disposed on the first side wall of the first light emitting unit, and the inclined connecting part is inclined with respect to a surface of the base substrate facing the at least two light emitting units; and
wherein the light emitting diode chip further comprises a first insulation layer, the first insulation layer comprises an inclined part sandwiched between the first side wall of the first light emitting unit and the inclined connecting part, at least a part of the inclined part is inclined with respect to the surface of the base substrate facing the at least two light emitting units at an inclination θ, and the inclination θ≤60°.

2. The light emitting diode chip of claim 1, wherein the light emitting diode chip comprises at least two bridging parts, each of the at least two bridging parts is configured to electrically connect the second semiconductor layer of the first light emitting unit with the first semiconductor layer of the second light emitting unit, and orthographic projections of the at least two bridging parts on the base substrate are spaced from each other.

3. The light emitting diode chip of claim 1, wherein the inclined part comprises a first side surface close to the first light emitting unit, a part of the first side surface is in contact with the first semiconductor layer of the first light emitting unit, and the first side surface is inclined with respect to the surface of the base substrate facing the at least two light emitting units at the inclination θ.

4. The light emitting diode chip of claim 3, wherein the inclined part comprises a first side surface close to the first light emitting unit, a part of the first side surface is in contact with the first semiconductor layer of the first light emitting unit, and comprises a first sub-side surface and a second sub-side surface; and
the first sub-side surface is inclined with respect to the surface of the base substrate facing the at least two light emitting units at an inclination a, the second sub-side surface is inclined with respect to the surface of the base substrate facing the at least two light emitting units at the inclination θ, and the inclination a is not equal to the inclination θ.

5. The light emitting diode chip of claim 4, wherein the first sub-side surface is closer to the base substrate than the second sub-side surface; and/or,
the inclination a is greater than the inclination θ.

6. The light emitting diode chip of claim 4, wherein the first side surface further comprises a platform surface connecting the first sub-side surface and the second sub-side surface, and the platform surface is parallel to the surface of the base substrate facing the at least two light emitting units.

7. The light emitting diode chip of claim 1, wherein the first side surface further comprises a third sub-side surface in contact with the light emitting layer of the first light emitting unit and a fourth sub-side surface in contact with the second semiconductor layer of the first light emitting unit;
each of the third sub-side surface and the fourth sub-side surface is inclined with respect to the surface of the base substrate facing the at least two light emitting units at the inclination θ.

8. The light emitting diode chip of claim 4, wherein the first insulation layer further comprises a first plane part, the first plane part is parallel to the surface of the base substrate facing the at least two light emitting units, the first plane part is located in an interval between the first light emitting unit and the second light emitting unit, and a width of the first plane part is less than or equal to a width of the interval.

9. The light emitting diode chip of claim 8, wherein the first plane part comprises a first sub-plane part and a second sub-plane part, the first sub-plane part is closer to the first light emitting unit than the second sub-plane part, and a height of the first sub-plane part is greater than a height of the second sub-plane part.

10. The light emitting diode chip of claim 1, wherein the light emitting diode chip further comprises an avoidance structure;
the avoidance structure comprises a first avoidance concave part located on at least a part of the first side wall, the first avoidance concave part causes at least a part of the first side wall to be concaved towards a first direction, and the first direction is a direction directing from the second light emitting unit to the first light emitting unit; and/or
the second light emitting unit comprises a second side wall close to the first light emitting unit, the avoidance structure comprises a second avoidance concave part located on at least a part of the second side wall, the second avoidance concave part causes at least a part of the second side wall to be concaved towards a second direction, and the second direction is a direction directing from the first light emitting unit to the second light emitting unit.

11. The light emitting diode chip of claim 10, wherein the bridging part comprises a third side wall facing an interval between the first light emitting unit and the second light emitting unit, the avoidance structure comprises a third avoidance concave part located on at least a part of the third side wall, the third avoidance concave part causes at least a part of the third side wall to be concaved towards a third direction, and the third direction is a direction directing from the interval to a body of the bridging part.

12. The light emitting diode chip of claim 1, wherein a contour of an orthographic projection of the light emitting diode chip on the base substrate has a shape of square.

13. The light emitting diode chip of claim 12, wherein orthographic projections of the at least two light emitting units on the base substrate are arranged symmetrically with respect to a geometric center of the square.

14. A display substrate comprising a light emitting diode chip of claim 1.

15. A display device comprising a light emitting diode chip of claim 1.
